(19) United States
(12) Patent Application Publication
(10) Pub. No.: US 2010/0230146 A1
(43) Pub. Date: Sep. 16, 2010

(54) CIRCUIT LAYER COMPRISING CNTS AND METHOD OF MANUFACTURING THE SAME

(76) Inventors: Eung Suek LEE, Gyunggi-do (KR); Je Gwang Yoo, Gyunggi-do (KR); Chang Sup Ryu, Gyunggi-do (KR); Jun Oh Hwang, Gyunggi-do (KR); Jee Soo Mok, Gyunggi-do (KR)

Correspondence Address: BLAKELY SOKOLOFF TAYLOR & ZAFMAN LLP, 1279 OAKMEAD PARKWAY, SUNNYVALE, CA, 94085-4040, US

(21) Appl. No.: 12/544,959

(22) Filed: Aug. 20, 2009

(30) Foreign Application Priority Data
Mar. 10, 2009 (KR) 10-2009-0020315

(51) Int. Cl. H05K 1/09; C25D 5/02

(52) U.S. Cl. 174/257; 205/126; 977/742

(57) ABSTRACT

Disclosed herein is a circuit layer including CNTs including an electroless copper plating layer formed on an insulating layer, and a CNT layer deposited on the electroless copper plating layer, thus the circuit layer has excellent electrical properties.

### CROSS REFERENCE TO RELATED APPLICATION

This application claims the benefit of Korean Patent Application No. 10-2009-0020315, filed Mar. 10, 2009, entitled “A structure of circuit layers including CNT and a fabricating method of circuit layers including CNT”, which is hereby incorporated by reference in its entirety into this application.

### BACKGROUND OF THE INVENTION

1. Technical Field

The present invention relates to a circuit layer including CNTs and a method of manufacturing the same.

2. Description of the Related Art

Currently, in electronic appliances and electronic parts, in consideration of specific resistance characteristics and economical aspects, copper (Cu) is being used for forming the connection between devices and the electrical connection between lower and upper layers. Generally, it is known that, when the section area of a circuit line width is smaller than the mean free path (MFP) of electrons in bulk metals, the specific resistance of the bulk metal is greatly increased by electron surface scattering and/or electron boundary scattering compared to the original specific resistance thereof. Therefore, when a circuit having a circuit line width of less then 400 nm is realized, copper (Cu) having a MFP of 400 nm cannot exhibit its original specific resistance characteristics.

Accordingly, recently, research has been actively conducted into forming a circuit pattern (X-Y interconnection) of a printed circuit board (PCB) and conducting interlayer connection (Z-interconnection) using carbon nanotubes (CNTs) which have a diameter of several nanometers (nm), is advantageously applied to ultra-fine wiring and has a maximum allowable current about 1000 times larger than that of copper.

Conventionally, attempts to realize a circuit pattern by applying artificial force to CNTs using an atomic force microscope (AFM) tip have been made, and attempts to conduct interlayer connection by vertically growing CNTs using chemical vapor deposition (CVD) have also been made. However, while a circuit pattern is being bent by applying artificial force to CNTs using an atomic force microscope (AFM) tip, the inherent characteristics of CNTs are lost, and thus the reliability of the realization of a circuit pattern cannot be assured. Therefore, research into these is not actively conducted.

FIGS. 1 to 4 are sectional views showing a conventional method of forming carbon nanotubes (CNTs) for interlayer connection on a silicon substrate.

First, as shown in FIG. 1, nanosized metal catalyst particles 12 are deposited on a silicon substrate 11, and then an insulating layer 13 is formed thereon.

Next, as shown in FIG. 2, laser via holes 14 are formed in the insulating layer 13.

Next, as shown in FIG. 3, carbon nanotubes 15 are vertically grown in the laser via holes 13 using a chemical vapor deposition (CVD) method which is a high-temperature (500˜1000° C.) synthesis method.

Next, as shown in FIG. 4, copper foil 16 is deposited on the insulating layer to be electrically connected with the carbon nanotubes 15, and thus the carbon nanotubes 15 are used as interlayer connectors.

However, the conventional method of forming carbon nanotubes is problematic in that a chemical vapor deposition (CVD), which is conducted at a high temperature of 500˜4000° C., is required in order to form the carbon nanotubes 15, so that a substrate which can be used even at high temperature in order to vertically grow the carbon nanotubes 15, for example, a silicon substrate 11, is also required, manufacturing time and cost are increased, and manufacturing processes are complicated.

Further, the conventional method of forming carbon nanotubes is problematic in that a metal catalyst 12 is additionally required, and a highly-airtight container is also required in order to deposit nanosized metal catalyst particles on the silicon substrate 11, thus increasing equipment costs.

As described above, it is improper to directly apply the conventional technology of forming carbon nanotubes using chemical vapor deposition to a process of manufacturing a printed circuit board.

### SUMMARY OF THE INVENTION

Accordingly, the present invention has been made to solve the above-mentioned problems, and the present invention provides a circuit layer including CNTs, which has excellent electrical properties, and a method of manufacturing the same.

An aspect of the present invention provides a circuit layer including carbon nanotubes (CNTs), including: an electroless copper plating layer formed on an insulating layer; and a CNT layer deposited on the electroless copper plating layer.

Here, the circuit layer may further include an electrolytic copper plating layer formed on the CNT layer.

Further, the circuit layer may further include a copper foil layer formed between the insulating layer and the electroless copper plating layer.

Another aspect of the present invention provides a method of manufacturing a circuit layer including CNTs, including: forming an electroless copper plating layer on an insulating layer; applying a plating resist having an opening to the electroless copper plating layer; forming a CNT layer on the electroless copper plating layer exposed by the opening through an electrolytic deposition process; and removing the plating resist and the electroless copper plating layer located beneath the plating resist.

Here, in the forming of the electroless copper plating layer, a copper foil layer may be formed between the insulating layer and the electroless copper plating layer.

Further, the forming of the CNT layer includes: preparing a deposition solution including carbon nanotubes (CNTs) having negative electric charges; and forming the CNT layer on the electroless copper plating layer by providing an electrolytic plating device in the deposition solution and then performing an electrolytic deposition process in a state in which the electroless plating layer exposed by the opening is provided as an anode.

Further, in the preparing of the deposition solution, the carbon nanotubes (CNTs) having negative electric charges may be formed by immersing them into an acid solution.

Further, the method may further include: forming an electrolytic copper plating layer on the CNT layer between the forming of the CNT layer and the removing of the plating resist and the electroless copper plating layer.

Various objects, advantages and features of the invention will become apparent from the following description of embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe the best method he or she knows for carrying out the invention.

### BRIEF DESCRIPTION OF THE DRAWINGS

The above and other objects, features and advantages of the present invention will be more clearly understood from the following detailed description taken in conjunction with the accompanying drawings, in which:

FIGS. 1 to 4 are sectional views showing a conventional method of forming carbon nanotubes (CNTs) for interlayer connection on a printed circuit board.

FIG. 5 is a sectional view showing a circuit layer including CNTs according to a first embodiment of the present invention;

FIG. 6 is a sectional view showing a modified example of the circuit layer including CNTs shown in FIG. 5;

FIG. 7 is a sectional view showing a circuit layer including CNTs according to a second embodiment of the present invention;

FIG. 8 is a sectional view showing a modified example of the circuit layer including CNTs shown in FIG. 7; and

FIGS. 9A to 15 are sectional views showing a method of manufacturing a circuit layer including CNTs according to an embodiment of the present invention.

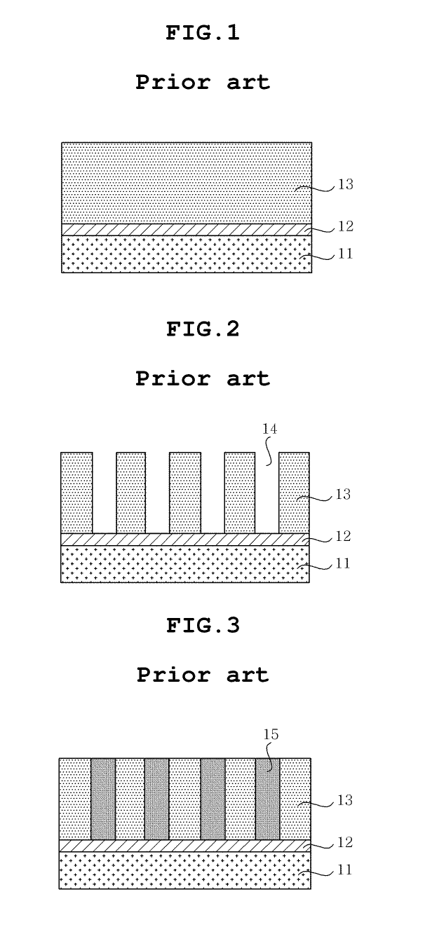

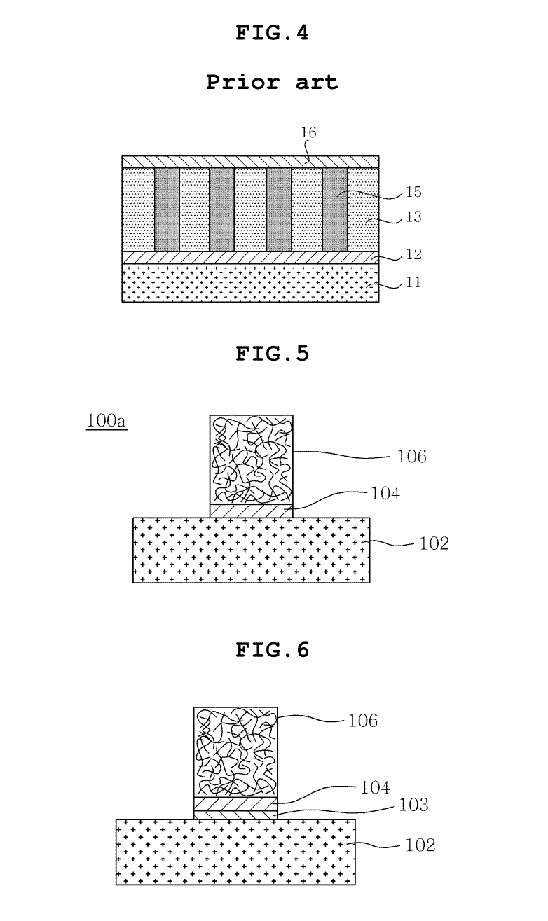

### DESCRIPTION OF THE PREFERRED EMBODIMENTS

The objects, features and advantages of the present invention will be more clearly understood from the following detailed description and preferred embodiments taken in conjunction with the accompanying drawings. Throughout the accompanying drawings, the same reference numerals are used to designate the same or similar components, and redundant descriptions thereof are omitted. Further, in the description of the present invention, when it is determined that the detailed description of the related conventional technologies makes the gist of the present invention obscure, the detailed description thereof may be omitted.

Hereinafter, preferred embodiments of the present invention will be described in detail with reference to the attached drawings.

Structure of a Circuit Layer Including CNTs

FIG. 5 is a sectional view showing a circuit layer including CNTs according to a first embodiment of the present invention, and FIG. 6 is a sectional view showing a modified example of the circuit layer including CNTs shown in FIG. 5.

As shown in FIG. 5, a circuit layer 100a including CNTs according to a first embodiment of the present invention includes an insulating layer 102, an electroless copper plating layer 104 formed on the insulating layer 102, and a CNT layer 106 formed on the electroless copper plating layer 104. Here, the CNT layer 106 is compactly deposited on the electroless copper plating layer to a thickness of about 6˜18 μm through an electrolytic deposition process. Further, the electroless copper plating layer 104 serves to increase the adhesion between the insulating layer 102 and the CNT layer 106.

Meanwhile, as shown in FIG. 6, a thin copper foil layer 103 may be formed between the insulating layer 102 and the electroless copper plating layer 104.

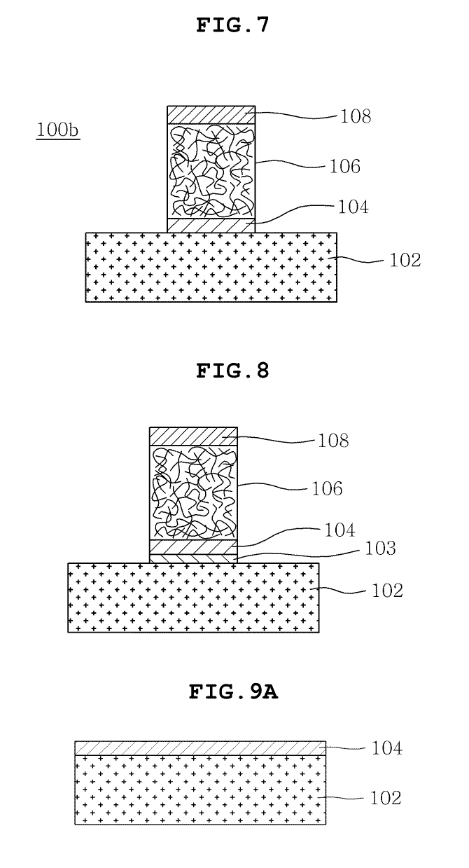

FIG. 7 is a sectional view showing a circuit layer including CNTs according to a second embodiment of the present invention, and FIG. 8 is a sectional view showing a modified example of the circuit layer including CNTs shown in FIG. 7.

As shown in FIG. 7, a circuit layer 100b including CNTs according to a second embodiment of the present invention includes an insulating layer 102, an electroless copper plating layer 104 formed on the insulating layer 102, a CNT layer 106 deposited on the electroless copper plating layer 104, and an electrolytic copper plating layer 108 formed on the CNT layer 106. Here, the electrolytic copper plating layer 108 serves to easily control the height of a circuit layer.

Meanwhile, as shown in FIG. 8, a thin copper foil layer 103 may be formed between the insulating layer 102 and the electroless copper plating layer 104.

Method of Manufacturing a Circuit Layer Including CNTs

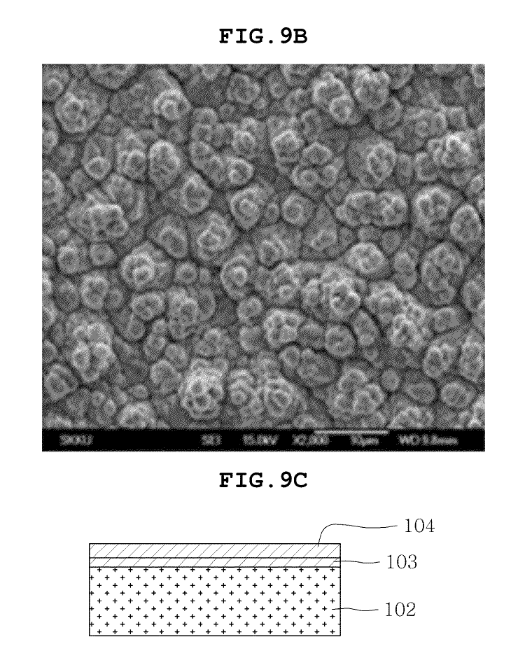

FIGS. 9A to 15 are sectional views showing a method of manufacturing a circuit layer including CNTs according to an embodiment of the present invention.

Hereinafter, a method of manufacturing a circuit layer including CNTs according to an embodiment of the present invention will be described in detail with reference to FIGS. 9A to 15.

The method of manufacturing a circuit layer including CNTs according to an embodiment of the present invention includes: forming an electroless copper plating layer on an insulating layer (S110); applying a plating resist having an opening to the electroless copper plating layer (S120); forming a CNT layer on the electroless copper plating layer exposed by the opening through an electrolytic deposition process (S130); and removing the plating resist and the electroless copper plating layer located beneath the plating resist excluding the opening (S140). Hereinafter, steps of the method of manufacturing a circuit layer including CNTs according to an embodiment of the present invention will be described in more detail with reference to the attached drawings corresponding to the respective steps. This embodiment is characterized in that a circuit layer is manufactured by forming a CNT layer through an electrolytic deposition process in a SAP method.

In S110, an electroless copper plating layer is formed on an insulating layer. FIGS. 9A and 9B show the processes corresponding to this step.

First, as shown in FIG. 9A, an electroless copper plating layer 104 is formed on an insulating layer 102. FIG. 9B is a photograph showing the formed electroless copper plating layer 104.

In this case, the electroless copper plating layer 104 is formed based on the principle that constituents of an electroless plating solution are deposited into copper by electrons supplied from a reductant after a catalyst is adsorbed on the surface of the insulating layer 102.

Here, the adsorption of the catalyst is conducted through a cleaning-conditioning process a catalyst pretreatment process a catalyst treatment process a catalyst reduction process, wherein: the cleaning-conditioning process serves to remove organic substances which can remain in the insulating layer 102 so as to improve wettability and serves to decrease surface tension using a surfactant so as to allow water-soluble chemicals to easily adhere to the inner wall of the insulating layer 102; the catalyst pretreatment process serves to immerse the insulating layer in a diluted catalytic chemical having a low concentration of 1˜3% prior to the treatment of the catalyst so as to prevent the chemicals used in the subsequent catalyst treatment process from being contaminated or so as to prevent the concentration of the chemicals from being changed; the catalyst treatment process serves to coat the insulating layer 102 with catalyst particles such as a palladium-tin complex compound or a palladium ion complex compound; and the catalyst reduction process serves to obtain a palladium (Pd) metal which really acts as a catalyst.

Meanwhile, as shown in FIG. 9C, in the present invention, a thin copper foil layer 103 having a thickness of 1 μm or less may be formed on the insulating layer 102 serving as a base layer, and then an electroless copper plating layer 104 may be formed on the thin copper foil layer 103, using a MSAP method. Hereinafter, for the convenience of description and illustration, the method of manufacturing a circuit layer using the SAP method will be described based on FIG. 9A.

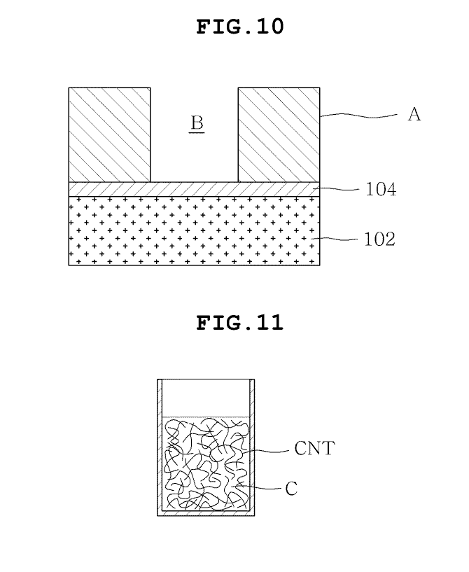

In S120, a plating resist A is applied onto the electroless copper plating layer 104 formed on the insulating layer 102, and then an opening B is formed in the plating resist A in order to form a circuit layer. FIG. 10 shows the process corresponding to this step.

That is, as shown in FIG. 10, a plating resist A, such as a dry film, is applied onto the electroless copper plating layer 104 formed on the insulating layer 102, and then an opening B is formed in the plating resist A in order to expose a circuit formation region through an exposure process.

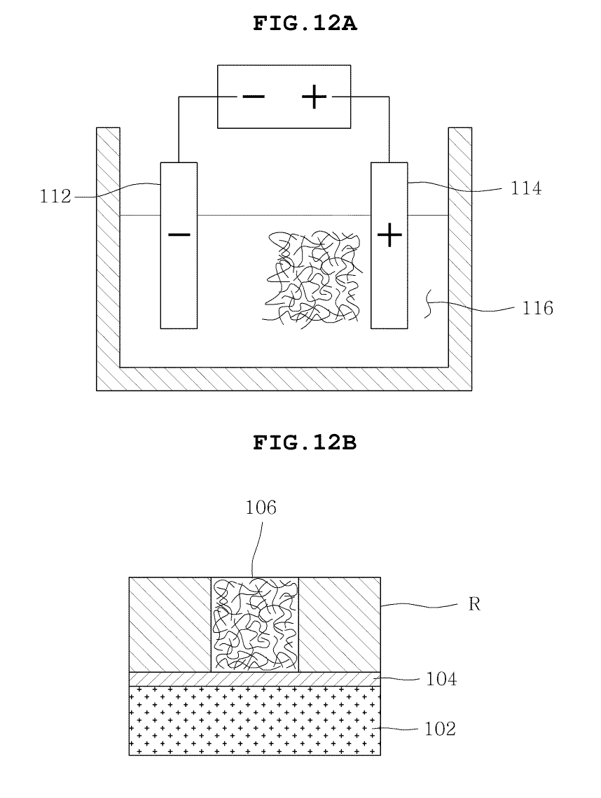

In S130, a CNT layer 106 is formed on the electroless copper plating layer 104 exposed by the opening B through an electrolytic deposition process. FIGS. 11 to 12 (12A to 12C) show the processes corresponding to this step.

First, as shown in FIG. 11, carbon nanotubes (CNTs) are immersed in an acid solution C to prepare CNTs having negative electric charges.

In this case, when CNTs are immersed in an acid solution, such as sulfuric acid, nitric acid, hydrochloric acid or the like, CNTs having a functional group such as a carboxyl group or the like, that is, CNTs having negative electric charges, are prepared.

For example, in this step, CNTs are immersed in a mixed acid solution of sulfuric acid (H₂SO₄) and nitric acid (HNO₃), are sonicated to refine and cut the CNTs, and then are refluxed, filtered and rinsed with deionized water.

Subsequently, as shown in FIG. 12A, a metal bar, serving as a cathode 112, and a subject to be deposited with CNTs, serving as an anode 114, are provided in a deposition solution 116 including the CNTs having negative electric charges, and then electric current is applied thereto to perform an electrolytic deposition process.

Here, the subject to be deposited with CNTs is the insulating layer 102 provided on one side thereof with the electroless copper plating layer 104 and the plating resist A having the opening B, shown in FIG. 10.

In this case, the CNTs having negative electric charges are deposited on the anode 114 by electrostatic attractive force. That is, as shown in FIG. 12B, a CNT layer 106 is formed on the electroless copper plating layer 104 exposed by the opening B. Meanwhile, FIG. 12C is a photograph showing the CNT layer 106 deposited on the electroless copper plating layer 104.

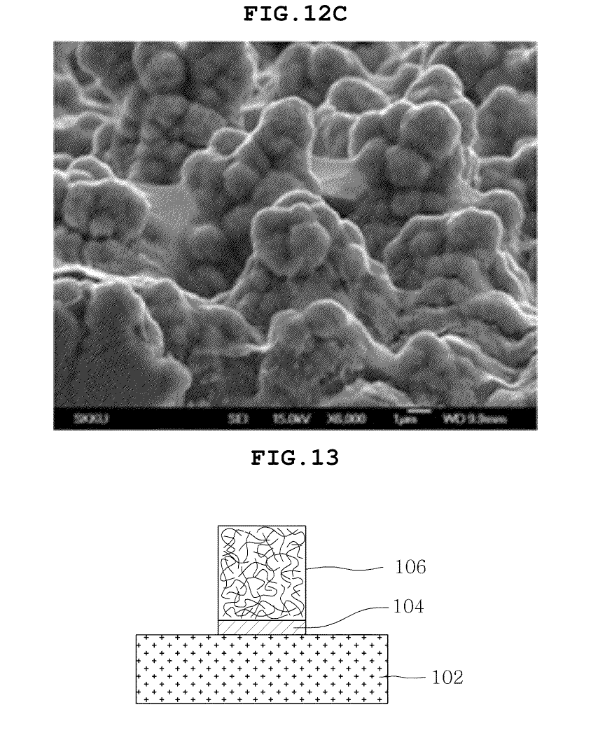

In S140, a plating resist A and an electroless copper plating layer 104 located beneath the plating resist excluding the opening B are removed to form a circuit layer. FIG. 13 shows the process corresponding to this step.

As shown in FIG. 13, the plating resist A, such as a dry film, is removed using a stripping agent, such as sodium hydroxide (NaOH), potassium hydroxide (KOH) or the like, and the electroless copper plating layer 104 located beneath the plating resist A is removed through flash etching and/or quick etching, thereby forming a circuit layer including a CNT layer.

Meanwhile, between S130 and S140, an electrolytic copper plating layer 108 may be formed on the CNT layer 106 (S135).

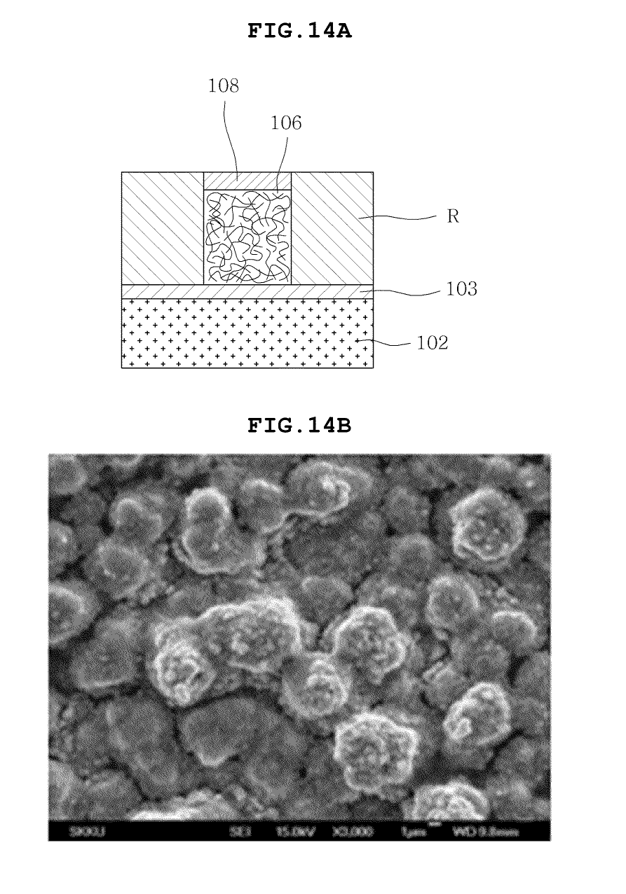

That is, as shown in FIG. 14A, the electrolytic copper plating layer 108 may be formed on the CNT layer 106 in a state in which the CNT layer 106 is formed in the opening B of the plating resist A at a predetermined height. Meanwhile, FIG. 14B is a photograph showing the electrolytic copper plating layer 108 formed on the CNT layer 106. Therefore, the height of a circuit layer can be controlled by the electrolytic copper plating layer 108.

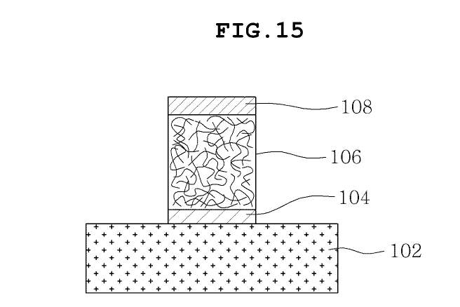

Subsequently, as shown in FIG. 15, the plating resist A and the electroless copper plating layer 104 located beneath the plating resist A are removed, thereby completing a circuit layer including a CNT layer.

As described above, according to the present invention, an ultra-fine circuit layer having excellent electrical properties can be realized because it includes carbon nanotubes (CNTs).

Further, according to the present invention, since CNTs can be deposited on an electroless copper plating layer through an electrolytic deposition process, they can also be used to form a circuit layer of a printed circuit board.

Further, according to the present invention, a circuit layer including CNTs can be manufactured by combining a conventional SAP method with a conventional MSAP method.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

The modifications, additions and substitutions of the present invention should be considered to fall within the scope of the present invention, and the scope of the protection of the present invention is clearly defined by the appended claims.

What is claimed is:

1. A circuit layer including carbon nanotubes (CNTs), comprising:
an electroless copper plating layer formed on an insulating layer; and
a CNT layer deposited on the electroless copper plating layer.

2. The circuit layer according to claim 1, further comprising: an electrolytic copper plating layer formed on the CNT layer.

3. The circuit layer according to claim 1, further comprising: a copper foil layer formed between the insulating layer and the electroless copper plating layer.

4. A method of manufacturing a circuit layer including CNTs, comprising:
forming an electroless copper plating layer on an insulating layer;
applying a plating resist having an opening to the electroless copper plating layer;
forming a CNT layer on the electroless copper plating layer exposed by the opening through an electrolytic deposition process; and
removing the plating resist and the electroless copper plating layer located beneath the plating resist.

5. The method according to claim 4, wherein, in the forming of the electroless copper plating layer, a copper foil layer is formed between the insulating layer and the electroless copper plating layer.

6. The method according to claim 4, wherein the forming of the CNT layer comprises:
preparing a deposition solution including carbon nanotubes (CNTs) having negative electric charges; and
forming the CNT layer on the electroless copper plating layer by providing an electrolytic plating device in the deposition solution and then performing an electrolytic deposition process in a state in which the electroless plating layer exposed by the opening is provided as an anode.

7. The method according to claim 6, wherein, in the preparing of the deposition solution, the carbon nanotubes (CNTs) having negative electric charges are formed by immersing them into an acid solution.

8. The method according to claim 4, further comprising: forming an electrolytic copper plating layer on the CNT layer between the forming of the CNT layer and the removing of the plating resist and the electroless copper plating layer.
